(19) United States
(12) Patent Application Publication
(10) Pub. No.: US 2016/0343933 A1
(43) Pub. Date: Nov. 24, 2016

(54) PRECURSOR COMPOSITION FOR ALKALINE EARTH METAL CONTAINING CERAMIC LAYERS

(71) Applicant: BASF SE, Ludwigshafen (DE)

(72) Inventors: Michael BAECKER, Koeln (DE); Martina FALTER, Swisttal-Buschhoven (DE); Jan BENNEWITZ, Sankt Augustin (DE); Christoph STEINBERG, Garbsen (DE); Christian WERNER, Hannover (DE)

(73) Assignee: BASF SE, Ludwigshafen (DE)

(21) Appl. No.: 15/034,346

(22) PCT Filed: Oct. 30, 2014
(86) PCT No.: PCT/EP2014/073359

§ 371 Date: May 4, 2016

(30) Foreign Application Priority Data
Nov. 5, 2013 (EP) 13191602.5

(51) Int. Cl. H01L 39/12; C09D 11/36; H01L 39/24; C04B 35/622; C04B 35/632; C09D 11/52; C04B 35/45

(52) U.S. Cl. CPC H01L 39/126; C09D 11/52; C09D 11/36; C04B 35/4508; C04B 35/62218; C04B 35/6325; H01L 39/2425; C04B 2235/3282; C04B 2235/6588; C04B 2235/656

(57) ABSTRACT

The present invention deals with precursor composition for alkaline earth metal containing ceramic layers. In particular, the present invention pertains to a precursor composition containing:(i) one or more soluble compounds of transition metals (ii) one or more soluble compounds of alkaline earth metals (iii) one or more soluble compounds of rare earth metals (iv) difluorinated carboxylate and/or partly fluorinated propionates (v) one or more solvents, wherein the difference between the boiling points of the corresponding acid of the components (i) to (iii) to the boiling point of component (iv) is less than 60 K.

The present invention deals with precursor composition for alkaline earth metal containing ceramic layers. In addition, the present invention deals with a process of forming a multi-layer high temperature superconductor.

Alkaline earth metal containing ceramic layers are used for (i) high-temperature superconducting (HTSC) films showing a huge market for the use for example in motors, electronics, cables and for (ii) dielectrics and ferroelectrics and many more. Thick (i.e., >1 μm) HTSC films, having a higher critical current (I_{c}), are preferred in applications requiring high current carrying capability, e.g., power transmission and distribution lines, transformers, fault current limiters, magnets, motors, and generators.

In order to achieve high speed production processes of these alkaline earth metal containing ceramic layers, chemical solution deposition (CSD) methods are required. With conventional solution-based techniques, thicker superconducting films are formed of multiple layers of HTS thin films, each having a thickness no greater than 1 μm (see for example Honjo et al, “Fabrication and growth mechanism of YBCO coated conductors by TFA-MOD process”, PHYSICA C, vol. 392, pp. 873-881, 2003).

Superconducting thin films may be deposited on buffered or unbuffered substrates by a variety of techniques including mainly decomposition of trifluoroacetate-based metal organic precursors (for example EP 1 334 525, EP 1 198 846). Only a few alternative fluorine-free routes are disclosed (see for example WO 2009/090062).

In the wet-chemical production of thin-film HTSCs, the HTSC layer must be crystallized after deposition as textured as possible on the substrate. This is influenced, among other things, by the composition of the precursor solution. Typically, trifluoroacetic acid is used in the production of the HTSC precursor solution along with at least one organic salt and/or one organic solvent and/or one organic complexing agent. If no trifluoroacetic acid is added to the HTSC precursor solution, the possibility that barium carbonate is obtained during the later heat treatment is very high. Barium carbonate is chemically and thermally very stable; consequently, barium bonded as carbonate is no longer available for the formation of the REBa₂Cu₃0ₓ superconductor and obstructs current transport at the grain boundaries. If solvents with trifluoroacetic acid are used for the salts, barium fluoride is obtained instead of barium carbonate. Barium fluoride will react during heat treatment with water vapor to barium oxide and hydrofluoric acid. The problem is that the water vapor will at first diffuse into the HTSC precursor layer and the hydrofluoric acid needs to diffuse out of the layer. That is why only comparatively thin layers can be grown. Moreover, pores are obtained in the HTSC layer by the diffusion.

Thus, precursor decomposition is the slowest and most critical step in the manufacturing of HTSC thin films. When a precursor film undergoes decomposition, a significant volume change occurs, generating stresses within the film. If uncontrolled, these stresses can cause extensive cracking in the resulting intermediate film, which in turn leads to failure of forming a HTS coating with a high I_{c}. Thus, it is important to accommodate these stresses.

One way to achieve this is control the decomposition rates of different precursors by careful selection of, e.g., decomposition temperature, line-speed, gas flow rate, and gas composition. See U.S. Pat. Nos. 6,669,774 and 6,797,313.

Another way of achieving a reduced reaction time by careful selection of the water vapor pressure during the reaction and crystallization step of the HTSC layer is disclosed in WO 2011/126629.

As it requires multiple coating and decomposition steps to produce a thick HTS film formed of multiple layers, it is difficult to greatly reduce the processing time without compromising the quality of HTSC film, e.g., an I_{c} drop. Thus, there is a need to develop new methods for making thick films.

It is a further disadvantage in the use of TFA that the obtained hydrofluoric acid is very poisonous and is still caustic when diluted.

One way of avoiding the excess of fluorine might be the use of mixed precursor, for example TFA and acetate. However, mixed precursors have the disadvantage of undefined decomposition products due to the statistical distribution of ligands. In addition, the distribution of the ligands might depend on the lifetime and thermal treatment of the precursor solution. Thus, the annealing process might be difficult to conduct.

WO 2009/090062 discloses a method for the wet chemical production of an HTSC on a substrate, wherein an HTSC precursor solution comprising no trifluoroacetate or other fluoroorganics may be utilized if the same is heated to a temperature T, during the heat treatment of the HTSC precursor, wherein the remaining substances of the HTSC precursor solution form at least a partial melt, which is below the temperature at which RE₂BaCuOₓ is formed, and which is deposited from the liquid phase while forming a peritectic. However, process control becomes more difficult because the process window to transfer the BaCO₃ into the RE₂BaCuOₓ is rather narrow.

The use of trifluoroacetate as precursor for dielectrics, for example Ba1-xCaxTiO3 (BCT), Ba1-xSrxTiO3 (BST), BaZrxTi1-xO3 (BZT) or BaTiO3 (BTO) is disclosed for example in Dielectric properties of random and <100> oriented SrTiO₃ and (Ba,Sr)TiO₃ thin films fabricated on <100> nickel tapes; Appl. Phys. Lett. 81, 3028 (2002). A fluorine-free route is disclose by Sigman et al. “Fabrication of Perovskite-Based High-Value Integrated Capacitors by Chemical Solution Deposition” Journal of the American Ceramic Society 04/2008; 91(6):1851-1857 or J Kunert et al 2011 Supercond. Sci. Technol. 24 085018.

US 2006/0 153 969 A1, EP 2 509 124 and U.S. Pat. No. 5,122,510 disclose methods of preparing superconducting films including difluoroacetate. However, the films obtained therein are still unsatisfactory for reliable high-quality production.

The task of the present invention is the finding of an improved method of making thick HTSC layers and a new precursor composition yielding in an improved HTSC layer.

In addition, that precursor composition for alkaline earth metal containing ceramic layers should have a reduced amount of fluorine and yielding in HTSCs films showing comparable or even better performance in comparison to the use of precursor composition containing trifluoroacetate.

The invention relates in part to the realization that during the formation of certain rare earth-alkaline earth-transition metal oxides (for example YBCO compounds such as YBa₂Cu₃O₇₋ₓ) defect formation can be reduced or prevented by selecting a precursor composition containing an appropriate salt of the rare earth metal, an appropriate salt of the alkaline earth metal, an appropriate salt of the transition metal, and one or more appropriate solvents.

Such precursor solutions can be used to form a relatively high quality (e.g., low defect density), relatively thick (e.g., at least about one to five micrometer thick) intermediate of the rare earth-alkaline earth-transition metal oxide (e.g., a metal oxyhalide intermediate) in a relatively short period of time (e.g., less than about five hours). The intermediate can then be further processed to form a rare earth-alkaline earth-transition metal oxide (e.g., an YBCO compound, such as YBa₂Cu₃O₇₋ₓ) having a low defect density and/or a relatively critical current density (e.g., at least about 0.5×10⁶ Amperes per square centimeter).

The present invention is directed towards a precursor composition containing:

(i) one or more soluble compounds of transition metals

(ii) one or more soluble compounds of alkaline earth metals

(iii) one or more soluble compounds of rare earth metals

(iv) difluorinated acetate and/or partly fluorinated propionates

(v) one or more solvents,

wherein the difference between the boiling points of the corresponding acid of the components (i) to (iii) to the boiling point of component (iv) is less than 60 K.

As used herein, “soluble compounds” of the metals refer to compounds of these metals that are capable of dissolving in the solvents contained in the precursor composition. Such compounds include for example, salts, oxides and/or hydroxides of these metals, whereas nitrates, acetates, alkoxides, iodies and/or sulfates are preferred salts. Especially preferred are carboxylates, particularly acetates and propionates.

Preferably the precursor composition contains a carboxylate salt of a rare earth metal, a difluorinated carboxylate of an alkaline earth metal, a carboxylate salt of a transition metal and optionally one or more solvents and/or additives.

The differences between the boiling points of the corresponding acids to all the components (i)-(iv) is less than 60 K, preferably less than 50 K, more preferably less than 40 K, even more preferably less than 20 K. Preferably the difference between these boiling points is in the range of 0 to 50 K, more preferred 0 to 25 K, even more preferred 0 to 10 K. Preferably the difference of the boiling points of all corresponding acids of the components (i) to (iii) to the boiling point of the component (v), the solvent, is more than 10 K, more preferably more than 20 K, even more preferably more than 30 K, even more preferably more than 50 K. Preferably the difference between these boiling points is in the range of 10 to 200 K, more preferred 20 to 150 K, even more preferred 50 to 100 K. More preferably, the boiling points of all corresponding acids of the components (i) to (iii) are higher than the boiling point of component (v), the solvent, in particular by the differences mentioned above.

An illustrative and non-limiting list of solvents includes water, acetonitrile, tetrahydrofuran, 1-methyl-2-pyrrolidinone, pyridine or alcohols, especially methanol, 2-methoxyethanol, butanol, isopropanol, alcohols with C6-C12 or mixtures of these solvents, more preferred methanol.

The precursor solution may contain stabilizers, wetting agents and/or other additives. The amount of these components may vary in the range of 0 up to 30 weight % relating to the total weight of the dry compounds used. Additives might be needed for adjusting the viscosity. An illustrative and non-limiting list of these additives include Lewis bases, TEA (triethanolamine), DEA (diethanolamine), tensides, PMAA (Polymetacrylic acid) and PAA (Polyacrylic acid), PVP (Polyvinylpyrolidone), Ethylcellulose.

Pinning centers may be used to increase critical current density or the critical magnetic flux density of an HTSC. The pinning centers can be formed in the HTSC by adding pinning-center-causing substances to the precursor solution. These substances may include, but is not limited to, soluble metal salts, excess metal in the precursor solution, or insoluble nanoparticles (wherein the precursor solution is a suspension).

Preferably the transition metal of component (i) is copper. Every carboxylate can be applied, preferred propionates. Especially preferred is copper propionate, particularly non-halogenated copper propionate.

Typically, the alkaline earth metal of component (ii) is barium, strontium or calcium. The preferred alkaline earth metal is barium. Every carboxylate can be applied, preferred fluorine containing carboxylates. Especially preferred is difluorinated acetate and/or partly-fluorinated propionate.

Every rare earth metal of component (iii) can be applied, preferred HREE like yttrium, dysprosium, erbium, preferably yttrium. Every carboxylate can be applied, preferred propionates. Especially preferred is yttrium propionate.

Preferably difluorinated acetate is used as component (iv). Preferably, alkaline earth metal difluorinated acetate are used. The alkaline earth metal is barium, strontium or calcium. The preferred alkaline earth metal is barium. In the case of alkaline earth metal difluorinated acetate, component (ii) and (iv) are combined.

Barium difluorinated acetate might be prepared by adding bariumcarbonate in water at room temperature. During a couple of hours difluoroacetic acid might be added by dropping. The temperature might be raised to about 50 to 100° C. during or after the adding of difluoroacetic acid. The reaction mixture should be stirred for a couple of hours. The reaction mixture might be filtered. The remaining solvents in the filtrate might be removed until crystallization. The product might be cooled and dried.

The atomic amount of the transition metal, alkaline earth metal and rare earth metal is typically in the range of 3:1 to 3:0.8 to 2, preferred between 3:1.4 to 2:1 to 1.7.

The metal concentration of the precursor solution is typically in the range of 0.3 to 2.4, preferred 0.6 to 1.8.

In general, the precursor composition can be prepared by combining the salts of the rare earth, the transition metal and the alkaline earth metal with the desired solvents and optionally the additives including wetting agents and/or further stabilizers. Additives can be added to the salts before dissolving them or afterwards.

The present invention is additionally directed to a process of forming a high temperature superconductor comprising disposing the precursor composition according to the invention on the surface of an underlying layer.

Subsequent to formation of the precursor composition, the composition can be disposed on the surface of an underlying layer, for example buffer layer, superconducting layer, substrate. Generally, the amount of the solvent(s) and/or water used in the precursor composition can be selected based upon the technique that will be used to dispose the precursor composition on the surface of the underlying layer.

The precursor composition can be disposed on the substrate or buffer-treated substrate by a number of methods, which are designed to produce coatings of substantially homogeneous thickness. For example, the precursor composition can be disposed using spin coating, slot coating, gravure coating, dip coating, tape casting, spraying or ink-jet printing, preferably continuous coating systems, especially ink-jet printing.

The ink-jet printing can be conducted as known by the skilled person in the art, for example Mosiadz et al. “Inkjet printing, pyrolysis and crystallization of YBa₂Cu₃O_{7-δ} precursor layers for fully chemical solution deposited coated conductors”, Physics Procedia 36 (2012), 1450-1455 or Juda et al. “superconducting properties of YBCO coated conductros produced by inkjet printing” Przeglad Elektrothechniczny, ISSN 0033-2097, R. 88 NR 7a12012.

Subsequent to being disposed on the surface of the underlying layer, the solution composition is treated to form a layer of superconductor material. This treatment generally involves heating at appropriate rates and in an appropriate gas environment so that during conversion of the precursor composition to the metal intermediate, minimal alkaline earth carbonate forms and minimal cross-linking occurs between discrete transition metal molecules. The intermediate is then advantageously further heated to form the desired superconducting material.

In general, the precursor composition can be annealed using a variety of reaction conditions, including gas environment and temperature, for example described in Knoth et al. “Chemical solution deposition of YBa₂Cu₃O₇₋ₓ coated conductors”, Curr. Opin. Solid State Mater. Sci. 10 (2006) 205-216.

Preferably the annealing step is conducted as a two or three-step process (a pyrolysis-, a densification and a reaction-plus recrystallization-step) including at least one heating step up to less than 500° C., more preferred up to less than 450° C., even more preferred up to less than 400° C. in a water vapour containing flowing gas atmosphere (pyrolysis step). The gas atmosphere contains typically water in an amount of 2 g/m³ gas to 25 g/m³ gas, preferably 2 g/m³ gas to 25 g/m³ gas, more preferred less than 5 g/m³ gas, nitrogen in an amount of 0 to 95 vol-%, oxygen in an amount of 5 to 100 vol-% and optionally inert gases in an amount of 0 to 100% substituting the nitrogen, for example (21% O₂+70% N₂, together 600 sl/h with additional 11 g water vapor).

A next separate step for densification at about 550° C. to 700° C., preferred at 600-650° C. in an O-reduced wet atmosphere can be provided. Otherwise this will be included in the further step.

The gas atmosphere during the further annealing process (reaction-plus recrystallization-step) up to the crystallization temperature of 700 to 850° C. can be varied or changed during different annealing temperatures. For example, for temperatures up to 800° C. in the final crystallization an oxygen pressure of about 100 to 5000 ppm in inert gas or nitrogen with water vapor from concentrations of around 10 g/scm up to 200 g/scm reaction gas flow are suitable.

Advantageously a turbulent flow is produced at the film substrate as described in EP 1419538. Under such conditions, the local gas composition at the interface is maintained essentially the same as in the bulk gas. Thus, the concentration of the gaseous products/reactants in the film is not controlled by the diffusion through the gas/film surface boundary layer conditions, but rather by diffusion through the film.

Advantageously the decomposition of the precursor composition and the forming of barium flouride and/or oxyfluoride is completed below 375° C., preferably below 360° C.; more preferred below 350° C. Advantageously the decomposition of the precursor composition and the forming of barium flouride and/or oxyfluoride does not start below 200° C., preferably not below 225° C.; more preferred not below 250° C. Advantageously the forming of barium fluoride occurs in a temperature range from 200 to 375° C., preferably from 225 to 360° C., more preferred from 250 to 350° C.

It is understood that several HTSC precursor compositions can be applied to the substrate or buffer-treated substrate and can then be heat-treated. Similarly, a further HTSC layer can be applied to an HTSC layer. Preferably one or more HTSC precursor layers may be applied successively on the substrate or buffer-treated substrate. Preferably the next layer of the precursor composition is applied after the pyrolysis step of the underlying layer, in order to keep the diffusion lengths involved as short as possible.

Preferably the total thickness of the HTSC layers after total conversion is in the range of 500-7000 nm. Preferably a thickness of 500 to 5000 nm, more preferred 600 to 3000, can be formed of 1 to 5 layers of HTS thin films.

Preferably the structure of the HTSC layers is mainly biaxially textured, the misorientation is preferably below 20% for tilts more than 5° relative to the perpendicular orientation on the substrate, more preferred below 10%, even more preferred below 5%. Preferably the pore volume of the HTSC layers is below 10% (average over 10⁵ μm³).

Preferably the value of the atomic ratio of Y/Cu of the final film (after pyrolysis) divided by the atomic ratio of Y/Cu of the precursor-solution is between 0.8 and 1.2, preferably between 0.9 and 1.1. (measured by ICP analyses in a volume 10⁻⁴ cm³).

Advantageously, the rare earth metal-alkaline earth metal-transition metal oxide layer contains in the intermediate stage after the pyrolysis defects within the intermediate of less than about 10% percent of any volume element of the intermediate defined by a projection of one square centimeter of a surface of the intermediate.

The rare earth metal-alkaline earth metal-transition metal oxide layer has advantageously a critical current density of at least more than 10⁶ Amperes per square centimeter.

The substrate may be formed of any material capable of supporting buffer and/ or superconducting layers. For example suitable substrates are disclosed in EP 830 218, EP 1 208 244, EP 1 198 846, EP 2 137 330. Typically the substrate may be a metal and/or alloy strip/tape, whereas the metal and/or alloy may be nickel, silver, copper, zinc, aluminum, iron, chromium, vanadium, palladium, molybdenum, tungsten and/or their alloys. Preferably the metal and/or alloy strip are nickel based and contain 3 to 10 at-% tungsten. Laminated metal tapes, tapes coated with a second metal like galvanic coating or any other multi-material tape with suited surface can also be used.

The substrate is preferably textured, i. e. it has a textured surface on which the buffer layer or HTSC layer is deposited, with a texture transfer being made from the substrate to the HTSC. The metal substrates are typically 20 to 200 μm thick, preferably 40 to 100 μm. The length is typically greater than 1 m, the width is typically between 1 cm and 1 m. The tapes can be slit after coating with the HTSC (and maybe some further protective layers) to smaller widths, for example to 1-5 cm.

Advantageously the metal surface is modified in order to deposit a buffer layer or another intermediate layer epitaxially thereon and/or to deposit an oriented high-temperature superconductor layer thereon as describe in WO 2010/058031. Typically, the method includes subjecting the metal substrate surface to a polishing treatment, in particular an electropolishing treatment, and subjecting the metal substrate to a (post-)annealing after and/or before the surface polishing treatment and before a subsequent coating is performed involving epitaxial deposition of a layer of the HTSC coating arrangement. The polishing and/or annealing treatment may be repeated.

Polishing is advantageously performed up to a surface roughness of rms according to DIN EN ISO 4287 and 4288 of <15 nm. The roughness respectively refer to an area of 10×10 micro m within a grain boundary of a crystallite of the substrate surface, so that the grain boundaries of the metal substrate do not distort the specified roughness.

Preferably the post-annealing is conducted under temperature above 800° C., especially above 850° C. At the post-annealing treatment which follows the polishing treatment, an inert or reducing atmosphere can be employed, preferably a reducing atmosphere.

Advantageously, the superconductor article includes one or more buffer layers between the substrate and ceramic material. The buffer layer can be formed of any material capable of supporting the ceramic layer. For example, buffer layer can be formed of one or more layers of buffer layer material. Examples of buffer layer materials include metals and metal oxides, such as silver, nickel, TbOₓ, GaOₓ, CeO₂, yttria-stabilized zirconia (YSZ), Y₂O₃, LaAlO₃, SrTiO₃, Gd₂O₃, LaNiO₃, LaCuO₃, SrRuO₃, NdGaO₃, NdAlO₃ and/or some nitrides as known to those skilled in the art. Preferably yttrium-stabilized zirconium oxide (YSZ), various zirconates, such as gadolinium zirconate, lanthanum zirconate and the like, titanates, such as strontium titanate, and simple oxides, such as cerium oxide, magnesium oxide and the like. More preferred the buffer layer is made of lanthanum zirconate, cerium oxide, yttrium oxide, gadolinium-doped and/or strontium titanate. Even more preferred the buffer layer is made of lanthanum zirconate and cerium oxide.

For guaranteeing a high degree of texture transfer and an efficient diffusion barrier, the buffer layer typically consists of layer combinations comprising multiple, different buffer materials. In certain embodiments, a plurality of buffer layers, for example three or more, can be deposited by epitaxial growth on an original surface. Preferably the buffer layers consist of two or three layers made of lanthanum zirconate and one or more of cerium oxide as the uppermost buffer.

For the production of the coating solutions, it may be advantageous to heat and/or stir the solutions so that they boil under reflux. In addition, various additives can be mixed in the coating solution to have a positive influence on the coating process and to increase the stability of the solution. To improve the process, for example, wetting agents may be used (the agents reduce the surface tension of the coating solution and thus make possible a uniform coating over the surface and on the edges, while at the same time counteracting the formation of drops/beads during drying). In addition, gelling agents, which make possible a uniform drying of the coating without flakes, cracks and pores, may be used. To stabilize the solutions, e.g., antioxidants can also be used.

The coating of the substrate with the coating solution according to the invention can be carried out in various ways. The solution can be applied by dip-coating (dipping of the substrate in the solution, spin-coating (applying the solution to a rotating substrate), spray-coating (spraying or atomizing the solution on the substrate), capillary coating (applying the solution via a capillary), ink-jet printing, and similar techniques.

One or more of the buffer layers can be chemically and/or thermally conditioned as described in Knoth et al. “Chemical solution deposition of YBa₂Cu₃O₇₋ₓ coated conductors”, Curr. Opin. Solid State Mater. Sci. 10 (2006) 205-216.

Superconductor articles can also include a layer of a cap material which can be formed of a metal or alloy whose reaction products with the superconductor material (e.g., YBa₂Cu₃O₇₋ₓ) are thermodynamically unstable under the reaction conditions used to form the layer of cap material. Exemplary cap materials include silver, gold, palladium and platinum.

Preferably the high-temperature superconductor (HTSC) strip is formed via wet-chemical application of the metallic cover layer as described in EP 1 778 892. During the process, a metal-organic salt solution (an organometallic salt solution) or an inorganic metal salt solution is applied to an HTSC layer or an HTSC precursor layer. The metals contained in the solution (i.e., the contained metals) are deposited on the HTSC layer by either heating the solution (in the case the metal-organic salt solution) or by applying a reducing solution and subsequently heating the applied solutions (in the case the inorganic metal salt solution). Heating the metal salt solution or the metal salt/reducing agent solutions expedites the formation of the metal layer. In either case, the residues of the metal salt solution remaining on the metal layer after its preparation (i.e., the solvent and the remainder of the ligands of the respectively used metal salts) are removed from the metal layer by the application of heat, e.g., by decomposition, pyrolysis, and/or vaporization.

The coating, drying and annealing steps of all layers can generally be carried out both in the batch process and continuously in a RTR (reel-to-reel) process as described for example in “MOCVD of YBCO and Buffer Layers on Textured Ni Alloyed Tapes”, Stadel et al., IEEE Transactions an Applied Superconductivity 07/2007. Because of the lower handling cost, continuous systems are preferred.

Preferably, the coating, drying and annealing steps of all layers are carried out using chemical solution deposition methods.

In one embodiment, a multi-layer high temperature superconductor is provided and includes first and second high temperature superconductor coated elements. Each element includes a substrate, at least one buffer deposited on the substrate, a high temperature superconductor layer as described above, and a cap layer. The first and second high temperature superconductor coated elements are preferably joined at the cap layer(s).

HTSC are used in different fields as described by Backer et al. “Energy and superconductors—applications of high-temperature-superconductors”, Z. Kristallogr. 226 (2011) 343-351, for example as cables for current transport or as coils used as magnets e.g. in rotating machines.

Due to better reaction control and lower water partial pressure needed in the DFA-process, the pores resulting from water diffusion can be minimized. Thus, the total thickness of one HTSC layer can be increased and/or the reaction time can be decreased (diffusion is a slow process). In addition, the release of toxic hydrofluoric acid during the reaction process is reduced by one third (33%) compared to the use of TFA.

Conducting the present invention less fluorine has to be released resulting in less gas bubbles to form pores and less fluorine to be filtered or collected in the exhaust. In addition, the reaction takes place in a more defined (narrower) temperature range.

Due to the small difference in the boiling points of difluoroacetate and the corresponding acid of the components (i) to (iii), propionic acid, and the large difference to the boiling point of the solvent, evaporation of difluoroacetate can be minimized.

Although the avoiding of the excess of fluorine is under discussion for a couple of years no one published experiments in view of difluorinated and/or partly-fluorinated carboxylates up to now.

### EXAMPLES

1. Synthesis of Barium Difluoroacetate:

750 g water and 394.7 g BaCO₃ were provided. 384.1 g of difluoroacetic acid was added slowly over 5 h to the suspension. After 150 g of DFA was added white foam appeared. The rest of the TFA was added at elevated temperatures. Finally, the product was stirred for 2 hours at 70° C.

The suspension was filtered and the volume was reduced at 68° C. in a rotational evaporator.

After cooling to 30° C. under rotation and to 15° C. in a cooling bath, the product was dried. The yield was 156.42 g.

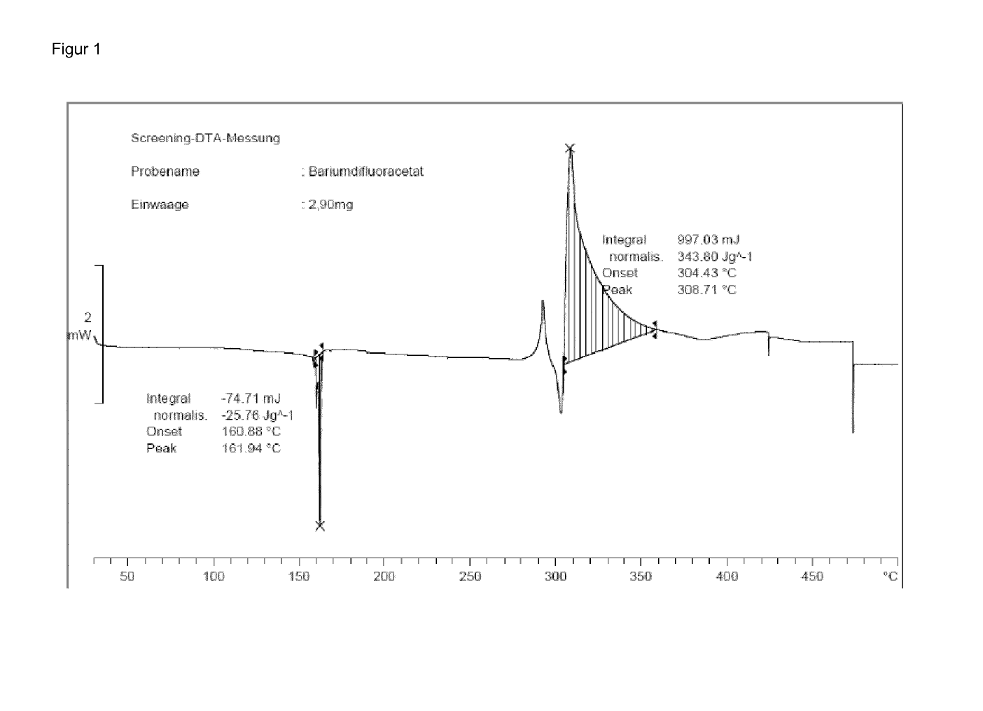

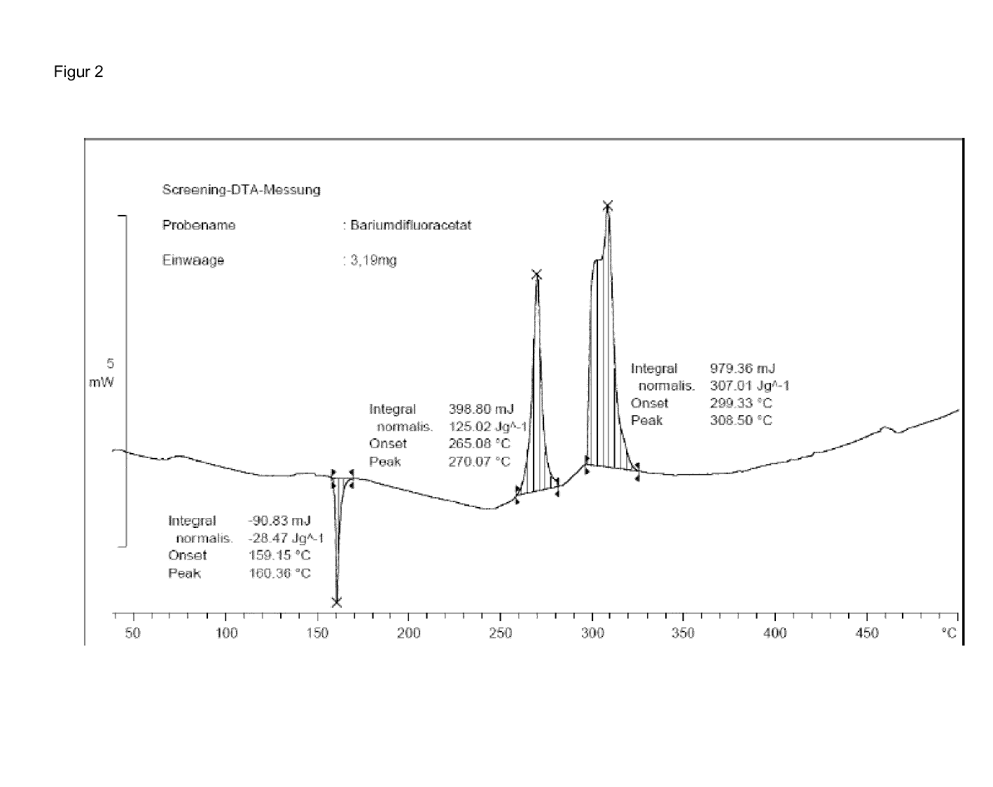

FIG. 1 shows the differential thermal analysis (DTA) measurements of barium difluoroacetate using aluminum crucible, FIG. 2 shows the DTA measurements of barium difluoroacetate using gold crucible.

2. Synthesis of the Precursor:

To synthesize 1 l of stochiometric precursor,

0.15 mol yttrium propionate

0.3 mol barium difluoroacetate

0.45 mol copper propionate

were dissolved in 800 ml of methanol (quantities refer to kationes) and stirred for 1 hour. 100 ml of a mixture of heavier alcohols and 7.5 g of ethyl celluloses were added and the mixture was stirred until everything was dissolved. The final solution was filled up with methanol to 1000 ml at 20° C.

3. Production of a Pyrolyzed Film from the Difluoroacetates Containing Precursor

The precursor was printed via ink-jet on a continuous substrate. Printing parameters were selected which lead to a 1.5 μm film after a single pyrolyses step. The film was heated slowly to 70° C. in dry atmosphere. Afterwards the atmosphere was switched to wet gas with DP=18° C. In order to start the pyrolysis the sample was heated within 3 more minutes to 160° C. and afterward linearly to 335° C. in 18 minutes. Cooling to RT took 5 more minutes.

The just pyrolysed film can be afterward crystallized. There are no differences in the further treatment between films deposited from difluoroacetates containing or trifluoroacetates containing or mixed precursors.

1. A precursor composition, comprising:
(i) one or more soluble compounds of transition metals;
(ii) one or more soluble compounds of alkaline earth metals;
(iii) one or more soluble compounds of rare earth metals;
(iv) difluorinated acetate and/or partly fluorinated propionate compound(s); and
(v) one or more solvents,
wherein the difference between the boiling points of the corresponding acid of the components (i) to (iii) to the boiling point of component (iv) is less than 60 K.

2. The precursor composition of claim 1, wherein the difference between the boiling points of the corresponding acid of the components (i) to (iii) to the boiling point of component (iv) is less than 40 K.

3. The precursor composition of claim 1, wherein the boiling points of all corresponding acids of the components (i) to (iii) are higher than the boiling point of component (v).

4. The precursor composition of claim 1, wherein the difference between the boiling points of the corresponding acid of the components (i) to (iii) and of component (iv) is more than 10 K to the boiling point of component (v), the solvent.

5. The precursor composition of claim 1, wherein the precursor composition contains Ethylcellulose as an additive.

6. The precursor composition of claim 1, wherein an alkaline earth metal di fluorinated acetate is used as components (ii) and (iv).

7. The precursor composition of claim 1, wherein propionates are used as soluble compounds of the components (i) and/or (iii).

8. A process of forming a high temperature superconductor, the process comprising disposing the precursor composition of claim 1 on the surface of an underlying layer.

9. The process of claim 8, wherein the precursor composition is disposed using spin coating, slot coating, gravure coating, dip coating, tape casting, spraying or ink-jet printing.

10. The process of claim 8, wherein the precursor composition disposed on the surface of the underlying layer is heated to form a layer of superconductor material.

11. The process of claim 10, wherein the heating is conducted as a two or three-step process including at least one heating step up to less than 500° C. in a water vapour containing flowing gas atmosphere and at least one heating step at about 550° C. to 700° C. in an O-reduced wet atmosphere.

12. The process of claim 11, wherein the gas atmosphere is in turbulent flow at the film substrate.
